(19) United States
(12) Patent Application Publication
(10) Pub. No.: US 2011/0140790 A1
(43) Pub. Date: Jun. 16, 2011

(54) FREQUENCY SYNTHESIZERS

(75) Inventors: Chun-Pang Wu, Taipei (TW); Hen-Wai TSAO, Taipei (TW); Jing-Shown WU, Taipei (TW)

(73) Assignee: NATIONAL TAIWAN UNIVERSITY, Taipei (TW)

(21) Appl. No.: 12/785,706

(22) Filed: May 24, 2010

(30) Foreign Application Priority Data
Dec. 14, 2009 (TW) 098142685

(51) Int. Cl. H03L 7/00

(52) U.S. Cl. 331/25

(57) ABSTRACT

A frequency synthesizer includes a fractional N phase locked loop (PLL), a sigma delta modulator, a phase adjustor and an adjust signal generator. The fractional N PLL generates an output signal according to an adjusted reference signal. A frequency of the output signal is a multiple of a frequency of a reference signal. The fractional N PLL includes a crystal oscillator generating the reference signal and a divider frequency dividing the output signal according to the multiple to generate a feedback signal. The sigma delta modulator generates a control signal to adjust the multiple accordingly. The phase adjustor adjusts a phase of the reference signal according to an adjust signal to generate the adjusted reference signal. The adjust signal generator generates the adjust signal according to an accumulation result of the sigma delta modulator.

### CROSS REFERENCE TO RELATED APPLICATIONS

This application claims priority of Taiwan Patent Application No. 098142685, filed on Dec. 14, 2009, the entirety of which is incorporated by reference herein.

### BACKGROUND OF THE INVENTION

1. Field of the Invention

The invention relates to a Phase Locked Loop (PLL), and more particularly to a Sigma-Delta PLL with phase compensation.

2. Description of the Related Art

FIG. 1 shows a conventional integer N PLL frequency synthesizer, which is used to generate a signal oscillated at a frequency as N, where N is a positive integer, times the frequency of the reference signal S_{Ref} generated by the crystal oscillator 101. In PLL 100, the phase detector 102 compares a phase difference between the reference signal S_{Ref} and an output signal of the frequency divider 105, and passes the comparison result to the charge pump 103. The charge pump 103 charges or discharges according to the comparison result so as to control the input voltage of the Voltage Controlled Oscillator (VCO) 104. The VCO 140 controls the oscillation frequency of the output signal according to the input voltage so as to generate the signal oscillated at a frequency as N times the frequency of the reference signal S_{Ref}. The output signal of the VCO 140 is further frequency divided by the frequency divider 105 and feedback to the phase detector 102. However, the choice of the frequency of the crystal oscillator and the loop bandwidth are both limited since only the signal having the frequency as an integer multiple of the frequency of the crystal oscillator can be generated based on the integer N PLL frequency synthesizer structure.

FIG. 2 shows a conventional fractional N PLL frequency synthesizer. The elements in PLL 200 and PLL 100 are almost the same, differing only in that the divisor of frequency divider 205 can be selected as N or (N+1) according to the control signal S_{Ctrl}. Frequency of the output signal of the VCO 104 is equivalent to an average of N and (N+1) times that of the reference signal. However, due to the variation in multiple divisors N and (N+1), an undesired spur with strong energy occurs in the spectrum of the output signal, which is called fractional spur.

FIG. 3 shows the spectrum of the output signal of the VCO. In the example, the frequency of the reference signal is 26 MHz and the divisor of the frequency divider is equivalent to

$$135 \frac{2}{130} .$$

Therefore, the frequency of the output carrier signal of the VCO is

$$26 \times 135 + 26 \times \frac{2}{130} = 3.5104 GHz .$$

However, due to the non-ideality of the circuit, undesired fractional spur, which is caused by the fractional portion of the divisor of the frequency divider, appears around the carrier frequency. As shown in FIG. 3, the frequency offset between the fractional spur and the carrier signal is only

$$26 \times \frac{2}{130} = 400 KHz .$$

Since the undesired fractional spur is very close to the desired signal, serious errors may occur when applying the output signal of the PLL frequency synthesizer.

Therefore, a novel design of a fractional N PLL frequency synthesizer, which can effectively eliminate undesired fractional spur caused by the fractional portion of the divisor of the fractional N PLL frequency synthesizer, is highly required.

### BRIEF SUMMARY OF THE INVENTION

Frequency synthesizers are provided. An exemplary embodiment of a frequency synthesizer comprises a fractional N phase locked loop (PLL), a sigma delta modulator, a phase adjustor and an adjust signal generator. The fractional N PLL generates an output signal according to an adjusted reference signal. A frequency of the output signal is a multiple of a frequency of a reference signal, and the fractional N PLL comprises a crystal oscillator generating the reference signal and a divider frequency dividing the output signal according to the multiple to generate a feedback signal. The sigma delta modulator is coupled to the divider and generates a control signal to adjust the multiple, accordingly. The phase adjustor is coupled to the crystal oscillator and adjusts a phase of the reference signal according to an adjust signal to generate the adjusted reference signal. The adjust signal generator is coupled to the sigma delta modulator and generates the adjust signal according to an accumulation result of the sigma delta modulator.

Another exemplary embodiment of a frequency synthesizer comprises a fractional N phase locked loop (PLL), a sigma delta modulator, a phase adjustor and an adjust signal generator. The fractional N PLL generates an output signal according to an adjusted reference signal. A frequency of the output signal is a multiple of a frequency of a reference signal, and the fractional N PLL comprises a crystal oscillator generating the reference signal and a divider frequency dividing the output signal according to the multiple to generate a feedback signal. The sigma delta modulator is coupled to the divider and generates a control signal to adjust the multiple, accordingly. The phase adjustor is coupled to the crystal oscillator and adjusts a phase of the reference signal according to an adjust signal to generate the adjusted reference signal. The adjust signal generator is coupled to the sigma delta modulator, estimates a phase difference between the feedback signal and the reference signal according to an accumulation result of the sigma delta modulator, and generates the adjust signal so as to compensate for the phase difference between the feedback signal and the reference signal.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 shows a conventional integer N PLL frequency synthesizer;

FIG. 2 shows a conventional fractional N PLL frequency synthesizer;

FIG. 3 shows the spectrum of the output signal of the VCO;

FIG. 4 shows a block diagram of a frequency synthesizer 400 according to an embodiment of the invention;

FIG. 5 shows an implementation of the sigma delta modulator according to an embodiment of the invention;

FIG. 6 shows an equivalent mathematic model of a sigma delta modulator according to an embodiment of the invention;

FIG. 7 shows a block diagram of a portion of the frequency synthesizer according to an embodiment of the invention;

FIG. 8 shows an equivalent mathematic model of a portion of the frequency synthesizer as show in FIG. 7;

FIG. 9 shows the frequency spectrum of the output signal S_{Out} generated in accordance with the reference signal after being phase adjusted by the phase adjustor, the adjust signal generator and the 1-order sigma delta modulator as shown in FIG. 7 according to an embodiment of the invention;

FIG. 10 shows an equivalent mathematic model of a 2-order sigma delta modulator according to an embodiment of the invention;

FIG. 11 shows an equivalent mathematic model of a portion of the frequency synthesizer according to another embodiment of the invention;

FIG. 12 shows the frequency spectrum of the output signal S_{Out} generated in accordance with the reference signal after being phase adjusted by the phase adjustor, the adjust signal generator and the 2-order sigma delta modulator according to an embodiment of the invention;

FIG. 13 shows an equivalent mathematic model of a 3-order sigma delta modulator according to an embodiment of the invention;

FIG. 14 shows an equivalent mathematic model of a portion of the frequency synthesizer according to another embodiment of the invention; and

FIG. 15 shows the frequency spectrum of the output signal S_{Out} generated in accordance with the reference signal after being phase adjusted by the phase adjustor, the adjust signal generator and the 3-order sigma delta modulator according to an embodiment of the invention.

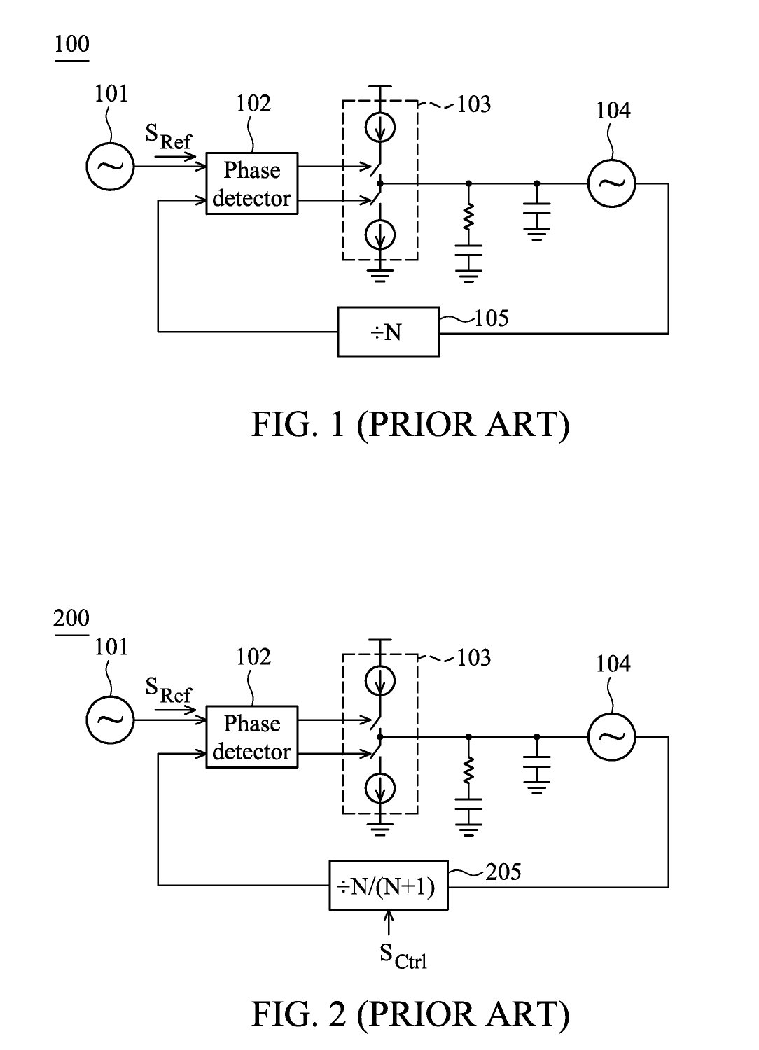

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

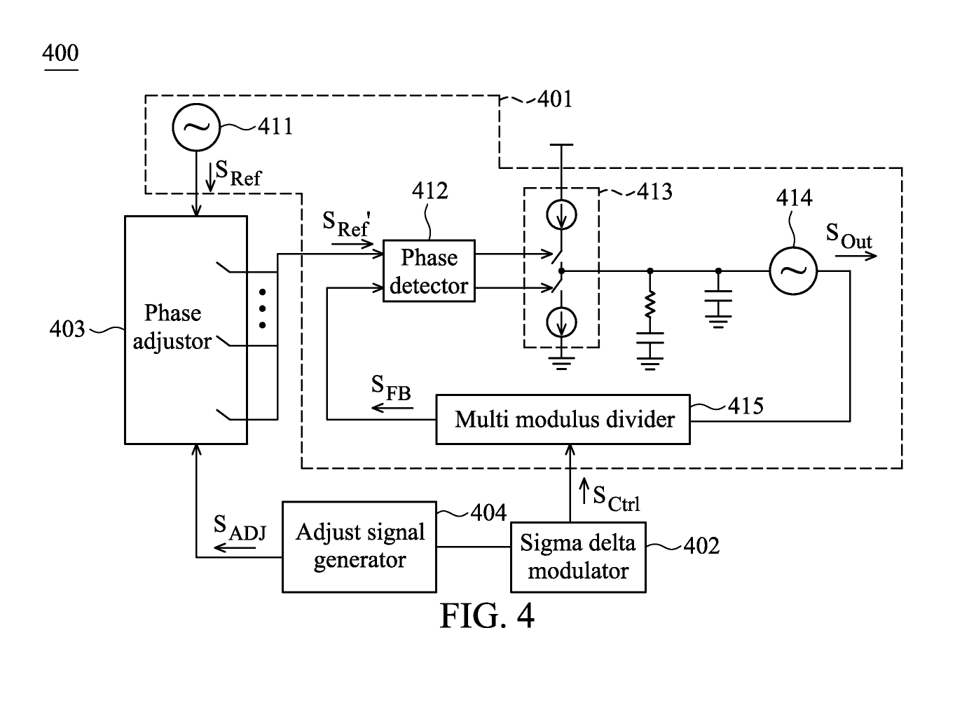

FIG. 4 shows a block diagram of a frequency synthesizer 400 according to an embodiment of the invention. The frequency synthesizer 400 comprises a fractional N phase locked loop (PLL) 401, a sigma delta modulator 402, a phase adjustor 403 and an adjust signal generator 404. The fractional N PLL 401 comprises a crystal oscillator 411, a phase detector 412, a charge pump 413, a voltage controlled oscillator (VCO) 414 and a multi modulus divider 415. The crystal oscillator 411 generates a reference signal S_{Ref}. The phase detector 412 compares a phase difference between an adjusted reference signal S_{Ref}′ and a feedback signal S_{FB} and generates a comparison result, accordingly. The charge pump 413 charges or discharges according to the comparison result so as to adjust a control voltage of the VCO 414. The VCO 414 adjusts the frequency of the output signal S_{Out} according to the control voltage. The multi modulus divider 415 frequency divides the output signal S_{Out} by using different divisors chosen in accordance with a control signal S_{Ctrl} to generate the feedback signal S_{FB}. Via the feedback mechanism of the PLL, a frequency of the output signal S_{Out} may be a multiple of a frequency of the reference signal S_{Ref}. For example, when it is desired to generate an output signal S_{Out} having a frequency as 10.1 times that of the reference signal S_{Ref}, the frequency synthesizer 400 may controls the multi modulus divider 415 to frequency divide the output signal S_{Out} by 10 for 9 times and by 11 for 1 time. Therefore, the divisor obtained d by the multi modulus divider 415 is equivalent to an average of the divisors 10 and 11 as

$$\frac{9 \times 10 + 11}{10} = 10.1 .$$

According to an embodiment of the invention, the sigma delta modulator 402 is coupled to the multi modulus divider 415 so as to generate the control signal S_{Ctrl} to change the value of the divisor. Different orders of the sigma delta modulator 402 may provide the control signal with different number of bits, so as to control the multi modulus divider 415 to switch between different numbers of the divisors. For example, a 1-order sigma delta modulator may provide a 1-bit control signal so as to control the multi modulus divider 415 to switch between two different divisors, and so on, as deduced by analogy. The adjust signal generator 404 is coupled to the sigma delta modulator 402 and generates the adjust signal S_{ADJ} according to an accumulation result of the sigma delta modulator 402. The phase adjustor 403 is coupled to the crystal oscillator 411 and adjusts a phase of the reference signal S_{Ref} according to the adjust signal S_{ADJ} to generate the adjusted reference signal S_{Ref}′. According to an embodiment of the invention, the phase adjustor 403 adjusts the phase of the reference signal S_{Ref} so as to make a phase difference between the adjusted reference signal S_{Ref}′ and the feedback signal S_{FB} to be smaller than a phase difference between the reference signal S_{Ref} and the feedback signal S_{FB}.

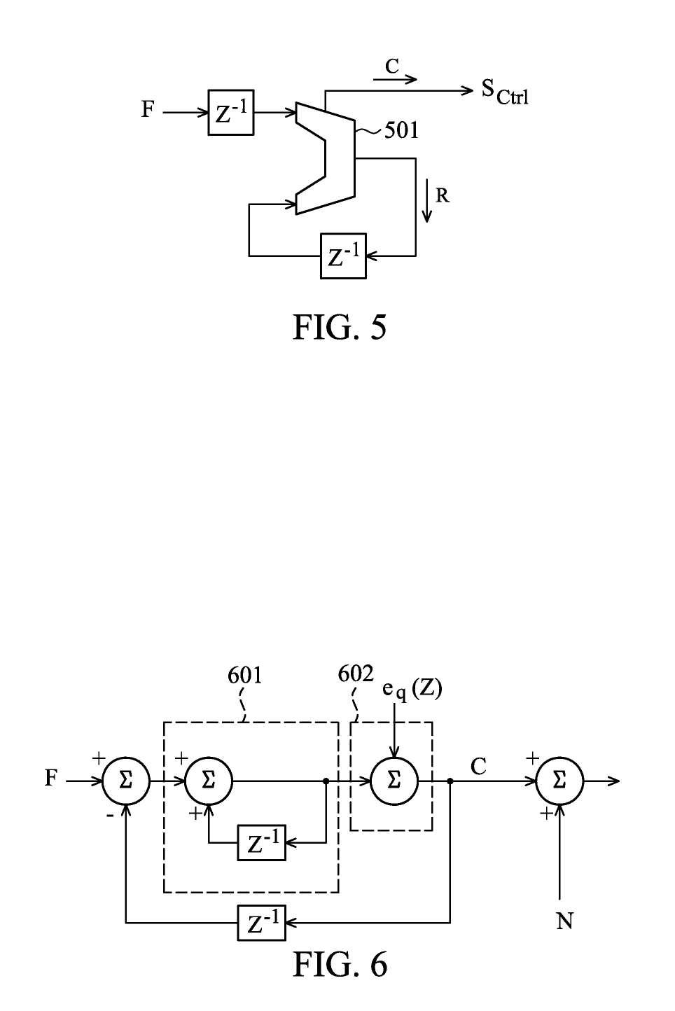

FIG. 5 shows an implementation of the sigma delta modulator according to an embodiment of the invention. The sigma delta modulator may comprise an accumulator 501. The accumulator 501 receives a fractional part F of the divisor as an input value. Take the divisor 10.1 as an example, F=0.1. The accumulator 501 continuously accumulates the input value F and outputs the accumulation result. The carry out (labeled by ‘C’ in FIG. 5) of the accumulation result is output from the first output terminal, and the remainder portion is output from the second output terminal (labeled by ‘R’ in FIG. 5). For example, the carry out C is 0 and R represents the current accumulation result of the accumulator until the accumulation result of the accumulator reaches 0.9. In this manner, the generated control signal S_{Ctrl} may be utilized to control the multi modulus divider 415 to keep the divisor as 10 in the former 9 periods. Once the accumulation result becomes 1, the carry out C becomes 1 and the remainder R becomes 0. At this time, the value of the control signal S_{Ctrl} changes as the carry out C changes, and therefore controls the multi modulus divider 415 to switch the divisor to 11. Thereby, a fractional number of the divisor may be equivalently obtained.

FIG. 6 shows an equivalent mathematic model of a sigma delta modulator according to an embodiment of the invention. The mathematic model 601 represents an accumulation operation and the mathematic model 602 represents a quantization operation. As shown in FIG. 6, by performing 1-bit quantization on the accumulation result, the value of carry out C is extracted, and added to the integer part N of the divisor so as to obtain the current divisor of the divider. For example, before the carry out of the accumulation result is generated, C=0 and N=10; thereby the obtained divisor of the divider is 10. When the carry out of the accumulation result is generated, C=1 and N=10; thereby the obtained divisor of the divider becomes 11.

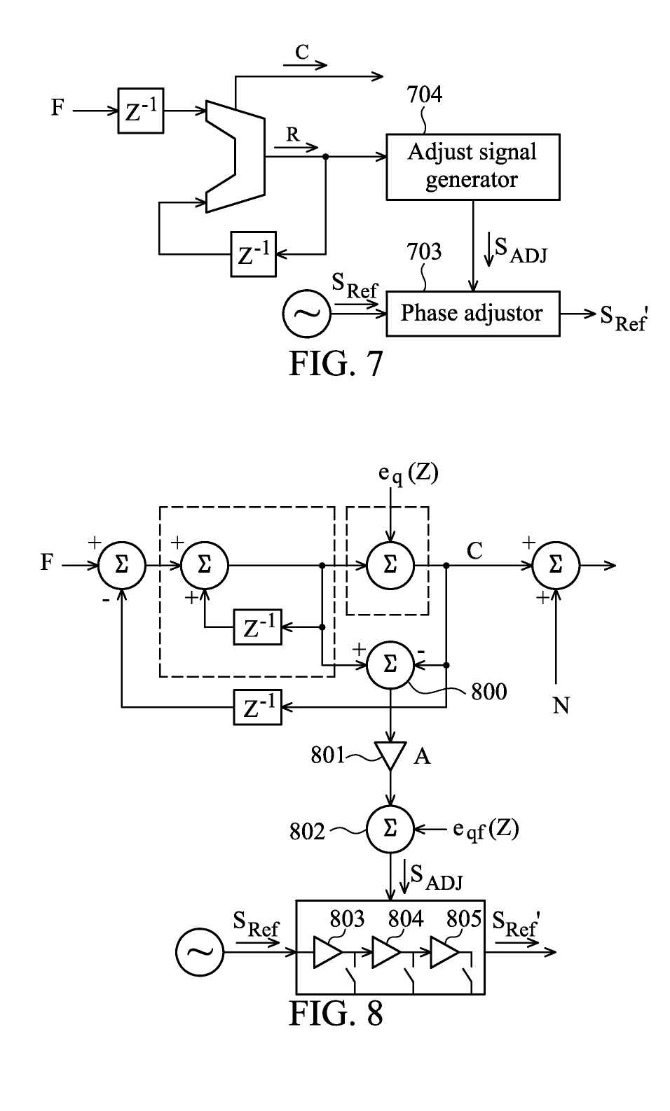

FIG. 7 shows a block diagram of a portion of the frequency synthesizer according to an embodiment of the invention. As shown in the figure, the adjust signal generator 704 receives the accumulation result of the accumulator and generates the adjust signal S_{ADJ}, according to the accumulation result. The phase adjustor 703 adjusts a phase of the reference signal S_{Ref} according to the adjust signal S_{ADJ} to generate the adjusted reference signal S_{Ref}′. According to an embodiment of the invention, the adjust signal generator 704 may comprise an amplifier amplifying the accumulation result according to a ratio and outputting the amplified accumulation result as the adjust signal S_{ADJ}. The phase adjustor 703 may comprise a plurality of delay units, each having a corresponding amount of delay so as to delay the phase of the reference signal S_{Ref}, and select an output of one of the delay units as the adjusted reference signal S_{Ref}′ according to the adjust signal S_{ADJ}.

FIG. 8 shows an equivalent mathematic model a portion of the frequency synthesizer as show in FIG. 7. As shown in the figure, the equivalent mathematic model of the adjust signal generator may comprise the adder 800, the amplifier 801 and the quantizer 802. The adder 800 obtains the fractional part of the accumulation result by subtracting the carry out C from the accumulation result of the accumulator. Take the input value F=0.1 as an example, the range of the output value of the adder 800 is 0˜0.9. The output value of the adder 800 is then amplified by the amplifier 801 according to a ratio A to obtain an amplified result. Utility of the quantizer 801 is equivalent to the quantizer 602, which is used to extract the integer part of the amplified result, so as to generate the adjust signal. The undesired fractional spur occurs because the rising edges of the pulses of the reference signal S_{Ref} generated by the crystal oscillator 101 cannot align with the rising edges of the pulses of the feedback signal S_{FB} when the divider switches between different divisors. Therefore, according to an embodiment of the invention, the adjust signal generator estimates the phase difference between the feedback signal S_{FB} and the reference signal S_{Ref} according to the current accumulation result, and the phase adjustor adjusts the phase of the reference signal S_{Ref} by using the delay units 803˜805, so as to pull the rising edges of the adjusted reference signal S_{Ref} and the feedback signal S_{FB} together, as close as possible; thereby reducing the phase difference between the adjusted reference signal S_{Ref}′ and the feedback signal S_{FB} so as to eliminate the fractional spur. Because the divisors of divider is switched in accordance with the accumulation result of the accumulator, in the embodiments of invention, the phase difference between the feedback signal S_{FB} and the reference signal S_{Ref} may be easily obtained by observing the changes in the accumulation result.

As described above, the phase adjustor may comprise a plurality of delay units (for example, the delay units 803˜805) delaying the phase of the reference signal S_{Ref}. Note that various types of delay structures may be utilized by the phase adjustor. As shown in FIG. 8, a delay line may be formed by multiple delay units. In addition, the phase adjustor may also utilize other kind of delay structures, such as a cyclic delay. While the invention has been described by way of example and in terms of preferred embodiments, it is to be understood that the invention is not limited thereto. Those who are skilled in this technology can still make various alterations and modifications without departing from the scope and spirit of this invention. Therefore, the scope of the present invention shall be defined and protected by the following claims and their equivalents.

According to an embodiment of the invention, the number of delay units and the amount of delay for each delay unit may be chosen arbitrarily. For example, the overall delay accumulated by the delay units may be set by the phase adjustor to equal to an oscillation period T_{VCO} of the VCO. Therefore, assuming that, as shown in FIG. 8, three delay units 803˜805 are comprised by the phase adjustor, the amount of delay Tᵤₙᵢₜ for each delay unit may be chosen as

$$Tunit = \frac{{T}_{vco}}{3} .$$

According to an embodiment of the invention, the ratio A of the amplifier 801 may be set to equal to the total number of delay units. For example, A=3. According to another embodiment of the invention, the ratio A may be set to A=T_{VCO}/Tᵤₙᵢₜ. In the embodiments of the invention, the adjust signal generator estimates that a phase difference between the feedback signal S_{FB} and the reference signal S_{Ref} has achieved a total amount of delay (n×Tᵤₙᵢₜ), which is accumulated by how many (n) delay units, according to the accumulation result. Also, an output signal of the corresponding delay unit (for example, the n-th delay unit) is selected as the adjusted reference signal S_{Ref}′ according to the estimation result so as to compensate for the phase difference between the feedback signal S_{FB} and the reference signal S_{Ref}. As an example shown in FIG. 8, when the range of the accumulation result is between 0.1˜0.3 and the ratio A=3, the range of the amplified result obtained by the amplifier is between 0.3˜0.9. At this time, the amplified result is smaller than 1 and no carry out is generated. Therefore, the carry out obtained by the quantizer is 0. The adjust signal generator may output a corresponding adjust signal S_{ADJ} so as to select the output of the delay unit 803 (the 0-th delay unit) as the adjusted reference signal S_{Ref}′. When the range of the accumulation result is between 0.4˜0.6, the range of the amplified result obtained by the amplifier is between 1.2˜1.8. At this time, the integer part of the amplified result is 1. That is, the carry out obtained by the quantizer is 1. The adjust signal generator therefore outputs the corresponding adjust signal S_{ADJ} so as to select the output of the delay unit 804 (the 1-st delay unit) as the adjusted reference signal S_{Ref}′. When the range of the accumulation result is between 0.7˜0.9, the range of the amplified result obtained by the amplifier is between 2.1˜2.7. At this time, the integer part of the amplified result is 2. That is, the carry out obtained by the quantizer is 2. The adjust signal generator therefore outputs the corresponding adjust signal S_{ADJ} so as to select the output of the delay unit 805 (the 2-nd delay unit) as the adjusted reference signal S_{Ref}′. In this manner, the phase difference between the feedback signal S_{FB} and the reference signal S_{Ref} is compensated for by the phase adjustor. Thus, fractional spur generated thereby is reduced due to the change in phase difference between the feedback signal S_{FB} and the reference signal S_{Ref}.

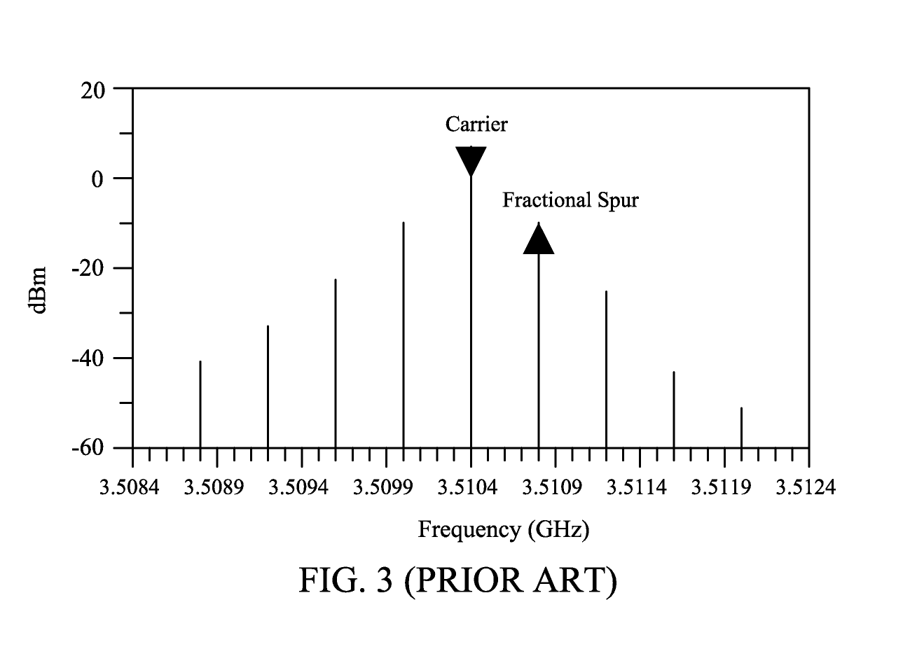

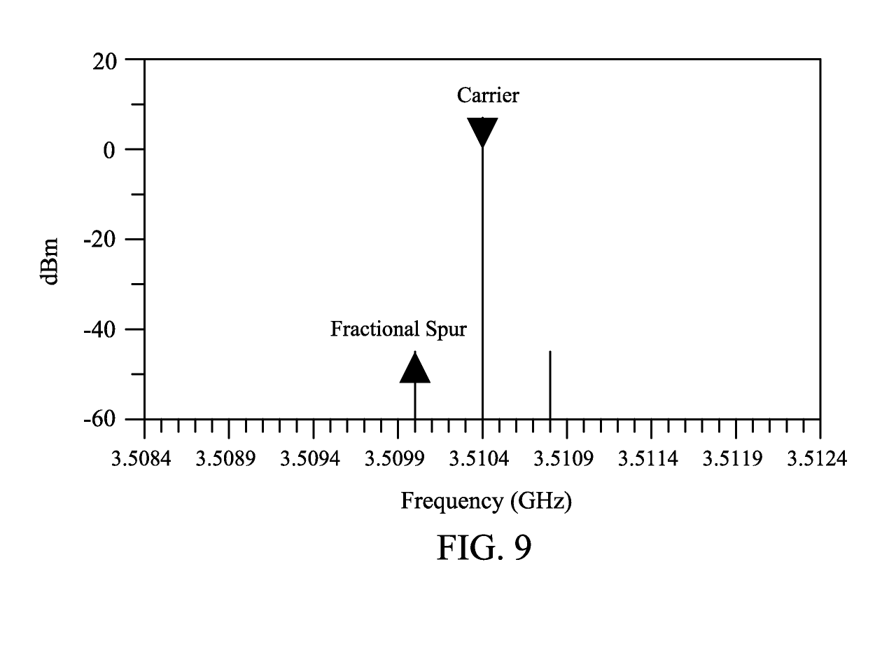

FIG. 9 shows the frequency spectrum of the output signal S_{Out} generated in accordance with the reference signal after being phase adjusted by the phase adjustor, the adjust signal generator and the 1-order sigma delta modulator as shown in FIG. 7 according to an embodiment of the invention. Comparing the frequency spectrum with the reference signal which is not phase adjusted, as shown in FIG. 3, with the reference signal which is phase adjusted, in the embodiments, it is shown that in FIG. 9 that energy of the undesired fractional spur around the carrier frequency may be lowered to about −50 dB, which can be easily distinguished from the output signal of the VCO (labeled by ‘Carrier’ as shown in the figure).

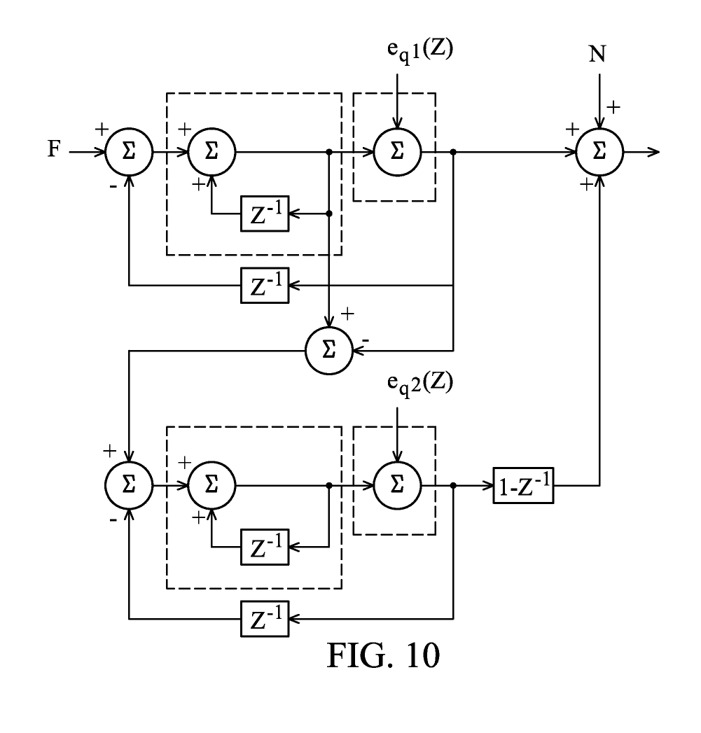

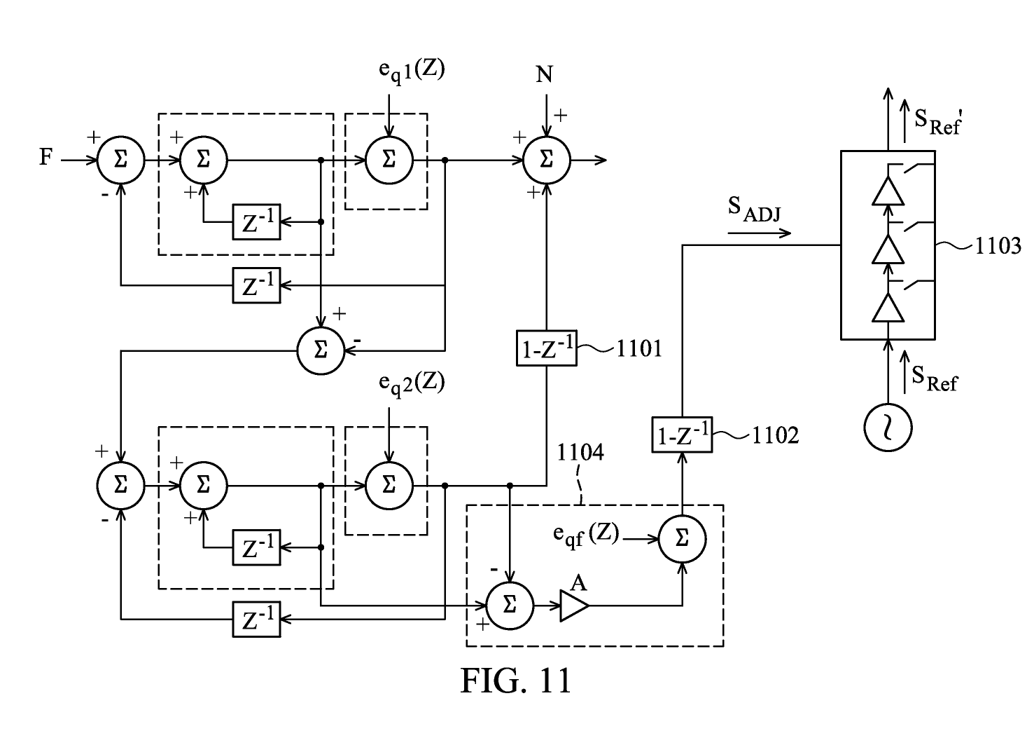

FIG. 10 shows an equivalent mathematic model of a 2-order sigma delta modulator according to an embodiment of the invention. As shown in the figure, the 2-order sigma delta modulator couples two stages of a sigma delta modulator to provide a 2-bits control signal. Therefore, the divisors of the multi modulus divider can be switched between four different values. FIG. 11 shows an equivalent mathematic model of a portion of the frequency synthesizer according to another embodiment of the invention. As shown in the figure, in the embodiment of the invention, the 2-order sigma delta modulator is utilized, where the adjust signal generator 1104 is coupled to the output terminal of the 2-order sigma delta modulator so as to estimate the phase difference between the feedback signal S_{FB} and the reference signal S_{Ref} according to the accumulation result of the 2-order sigma delta modulator, and generate the adjust signal S_{ADJ} to the phase adjustor 1103. The phase adjustor 1103 adjusts the phase of the reference signal S_{Ref} according to the adjust signal S_{ADJ} and generates the adjusted reference signal S_{Ref}′ to compensate for the phase difference between the feedback signal S_{FB} and the reference signal S_{Ref}. Note that the differentiation operation 1102 is used to match the differentiation operation 1101 of the 2-order sigma delta modulator.

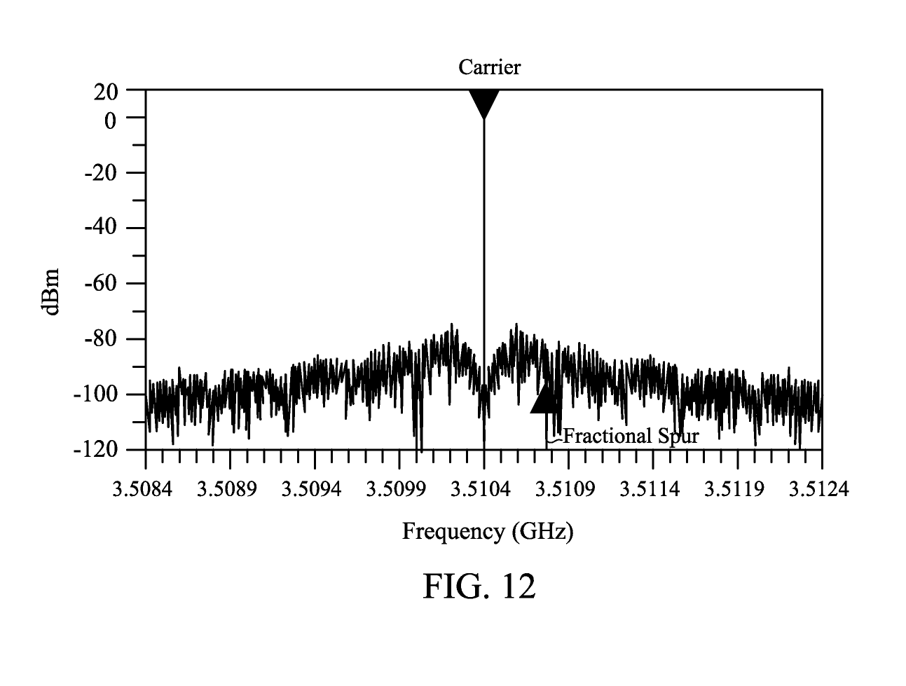

FIG. 12 shows the frequency spectrum of the output signal S_{Out} generated in accordance with the reference signal after being phase adjusted by the phase adjustor, the adjust signal generator and the 2-order sigma delta modulator according to an embodiment of the invention. As shown in the figure, the 2-order sigma delta modulator is utilized and by phase adjusting the phase of the reference signal, the energy of the undesired fractional spur around the carrier frequency is further lowered to about −90 dB.

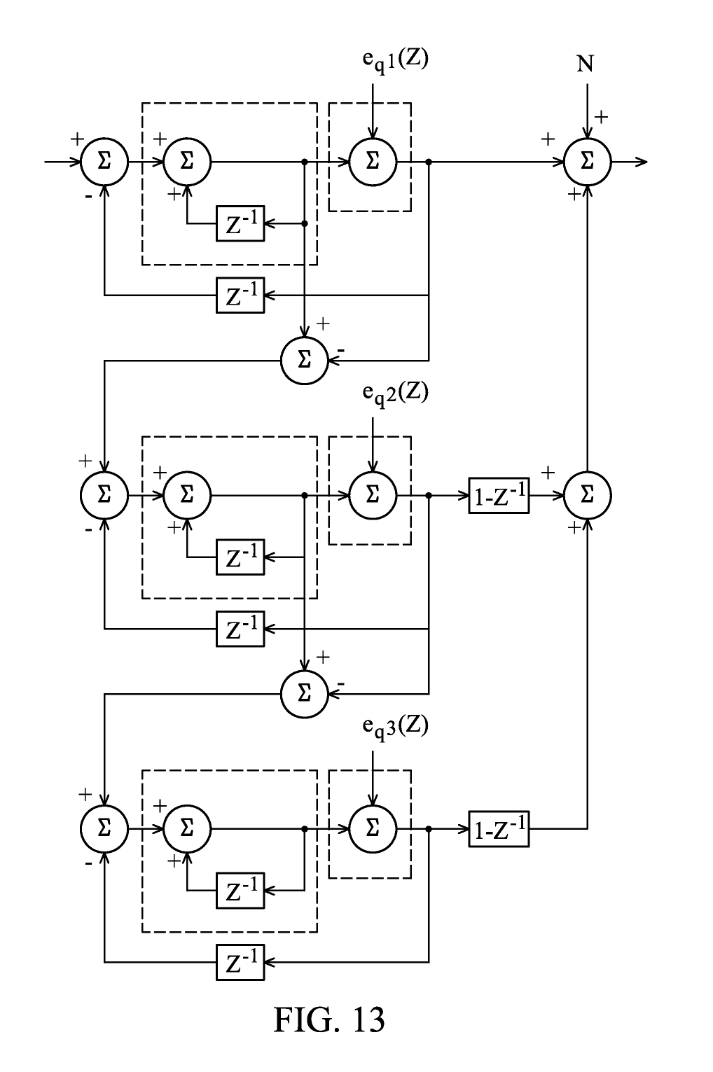

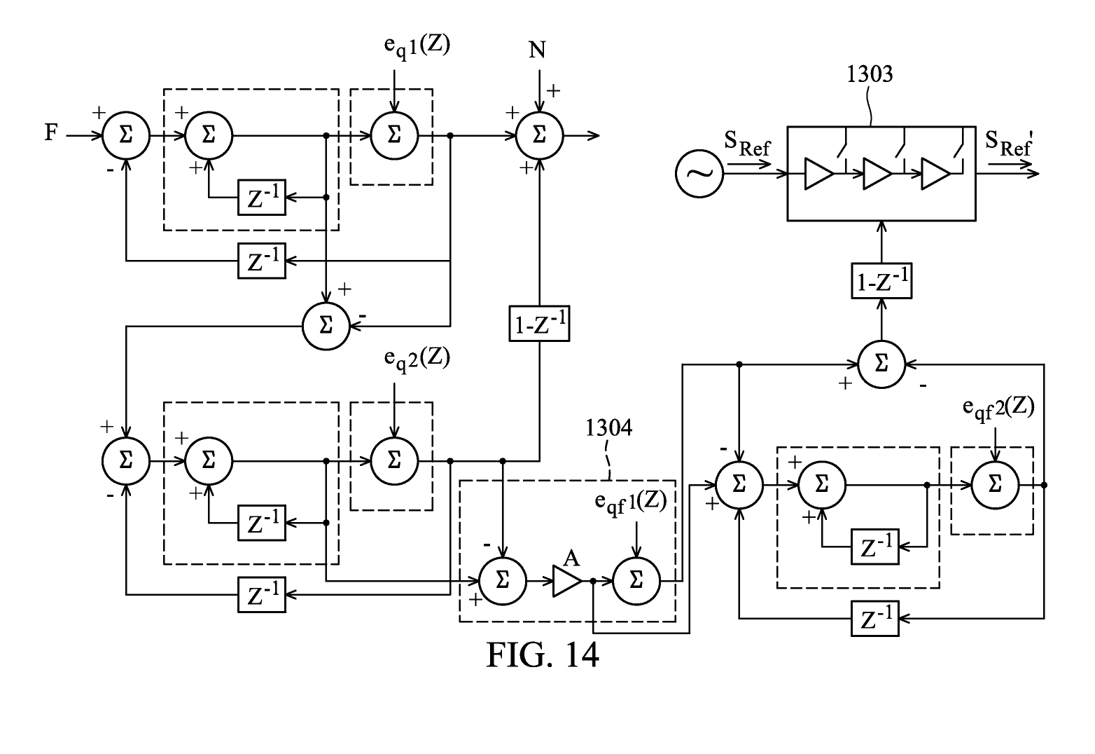

FIG. 13 shows an equivalent mathematic model of a 3-order sigma delta modulator according to an embodiment of the invention. As shown in the figure, the 3-order sigma delta modulator couples three stages of a sigma delta modulator to provide a 3-bits control signal. Therefore, the divisors of the multi modulus divider can be switched between eight different values. FIG. 14 shows an equivalent mathematic model of a portion of the frequency synthesizer according to another embodiment of the invention. As shown in the figure, in the embodiment of the invention, the 3-order sigma delta modulator is utilized, where the adjust signal generator 1304 is coupled to the output terminal of the second stage of sigma delta modulator, or in other embodiments of the invention, the adjust signal generator 1304 is coupled to the output terminal of the third stage of sigma delta modulator, so as to estimate the phase difference between the feedback signal S_{FB} and the reference signal S_{Ref} according to the accumulation result of the sigma delta modulator, and generate the adjust signal S_{ADJ} to the phase adjustor 1303. The phase adjustor 1303 adjusts the phase of the reference signal S_{Ref} according to the adjust signal S_{ADJ} and generates the adjusted reference signal S_{Ref}′ to compensate for the phase difference between the feedback signal S_{FB} and the reference signal S_{Ref}.

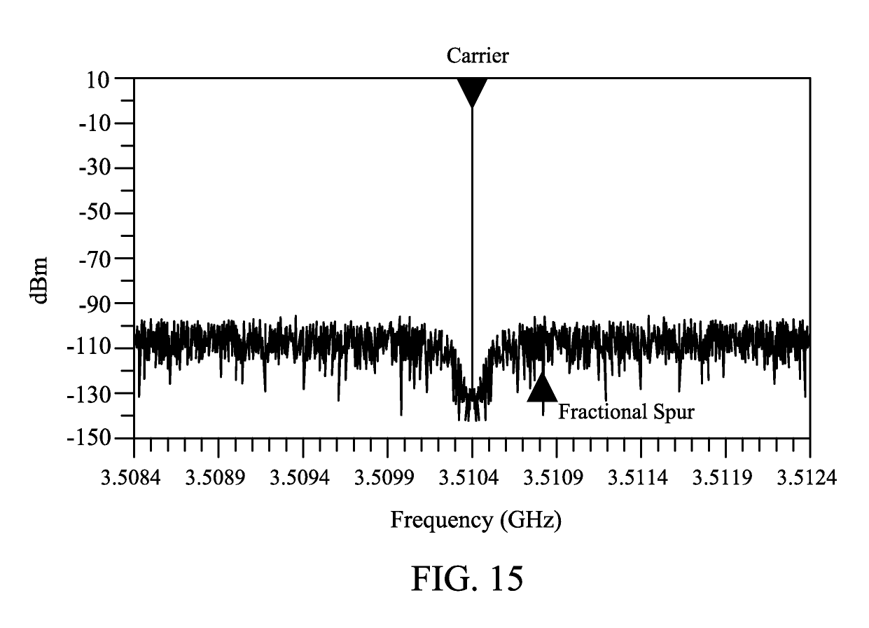

FIG. 15 shows the frequency spectrum of the output signal S_{Out} generated in accordance with the reference signal after being phase adjusted by the phase adjustor, the adjust signal generator and the 3-order sigma delta modulator according to an embodiment of the invention. As shown in the figure, the 3-order sigma delta modulator is utilized and by phase adjusting the phase of the reference signal, the energy of the undesired fractional spur around the carrier frequency is further lowered to about −110 dB.

Note that as shown from FIG. 7 to FIG. 15, the proposed phase estimation and adjustment method and corresponding hardware structures may be flexibly applied to different kinds of sigma delta modulator, such as the 1-order, 2-order and 3-order sigma delta modulators as previously described. Therefore, although the invention has been described by way of example and in terms of preferred embodiments, it is to be understood that the invention is not limited thereto. In addition, as previously described, various types of delay structures may be utilized by the phase adjustor, such as the delay line or the cyclic delay formed by multiple delay units. Although the delay line formed by three delay units is described as the embodiments of the invention, it is to be understood that the invention is not limited thereto. Those who are skilled in this technology can still make various alterations and modifications without departing from the scope and spirit of this invention. Therefore, the scope of the present invention shall be defined and protected by the following claims and their equivalents.

What is claimed is:

1. A frequency synthesizer, comprising:
a fractional N phase locked loop (PLL), generating an output signal according to an adjusted reference signal, wherein a frequency of the output signal is a multiple of a frequency of a reference signal, and the fractional N PLL comprises a crystal oscillator generating the reference signal and a divider frequency dividing the output signal according to the multiple to generate a feedback signal;
a sigma delta modulator, coupled to the divider and generating a control signal to adjust the multiple, accordingly;
a phase adjustor, coupled to the crystal oscillator and adjusting a phase of the reference signal according to an adjust signal to generate the adjusted reference signal; and
an adjust signal generator, coupled to the sigma delta modulator and generating the adjust signal according to an accumulation result of the sigma delta modulator.

2. The frequency synthesizer as claimed in claim 1, wherein the phase adjustor adjusts the phase of the reference signal so as to make a phase difference between the adjusted reference signal and the feedback signal to be smaller than a phase difference between the reference signal and the feedback signal.

3. The frequency synthesizer as claimed in claim 1, wherein the fractional N PLL further comprises:
a phase detector, comparing a phase difference between the adjusted reference signal and the feedback signal and generating a comparison result, accordingly;
a charge pump, charging or discharging according to the comparison result so as to adjust a control voltage; and
a voltage controlled oscillator (VCO), adjusting the frequency of the output signal according to the control voltage and outputting the output signal to the divider.

4. The frequency synthesizer as claimed in claim 1, wherein the sigma delta modulator comprises an accumulator accumulating an input value to generate the accumulation result.

5. The frequency synthesizer as claimed in claim 1, wherein the phase adjustor comprises a plurality of delay units, each having a corresponding amount of delay so as to delay the phase of the reference signal, and the phase adjustor selects an output of one of the delay units as the adjusted reference signal according to the adjust signal.

6. The frequency synthesizer as claimed in claim 5, wherein the adjust signal generator estimates that a phase difference between the feedback signal and the reference signal has achieved a total amount of delay, which is accumulated by how many delay units, according to the accumulation result, and generates the adjust signal according to the estimation result so as to select the output of a corresponding delay unit as the adjusted reference signal.

7. The frequency synthesizer as claimed in claim 5, wherein the adjust signal generator extracts a fractional part of the accumulation result, amplifies the fractional part of the accumulation result according to a ratio to obtain an amplified result, and the adjust signal generator further extracts an integer part of the amplified result to generate the adjust signal.

8. The frequency synthesizer as claimed in claim 7, wherein the phase adjustor selects the output of one of the delay units as the adjusted reference signal according to a value of the integer part.

9. The frequency synthesizer as claimed in claim 7, wherein the ratio relates to an amount of the delay units.

10. The frequency synthesizer as claimed in claim 7, wherein the ratio relates to the amount of delay of the delay units and an oscillation period of the VCO.

11. A frequency synthesizer, comprising:
a fractional N phase locked loop (PLL), generating an output signal according to an adjusted reference signal, wherein a frequency of the output signal is a multiple of a frequency of a reference signal, and the fractional N PLL comprises a crystal oscillator generating the reference signal and a divider frequency dividing the output signal according to the multiple to generate a feedback signal;
a sigma delta modulator, coupled to the divider and generating a control signal to adjust the multiple, accordingly;
a phase adjustor, coupled to the crystal oscillator and adjusting a phase of the reference signal according to an adjust signal to generate the adjusted reference signal; and
an adjust signal generator, coupled to the sigma delta modulator, estimating a phase difference between the feedback signal and the reference signal according to an accumulation result of the sigma delta modulator, and generating the adjust signal so as to compensate for the phase difference between the feedback signal and the reference signal.

12. The frequency synthesizer as claimed in claim 11, wherein the phase adjustor adjusts the phase of the reference signal so as to make a phase difference between the adjusted reference signal and the feedback signal to be smaller than the phase difference between the reference signal and the feedback signal.

13. The frequency synthesizer as claimed in claim 11, wherein the fractional N PLL further comprises:
a phase detector, comparing a phase difference between the adjusted reference signal and the feedback signal and generating a comparison result, accordingly;
a charge pump, charging or discharging according to the comparison result so as to adjust a control voltage; and
a voltage controlled oscillator (VCO), adjusting the frequency of the output signal according to the control voltage and outputting the output signal to the divider.

14. The frequency synthesizer as claimed in claim 11, wherein the sigma delta modulator comprises an accumulator accumulating an input value to generate the accumulation result.

15. The frequency synthesizer as claimed in claim 11, wherein the phase adjustor comprises a plurality of delay units, each having a corresponding amount of delay so as to delay the phase of the reference signal, and the phase adjustor selects an output of one of the delay units as the adjusted reference signal according to the adjust signal.

16. The frequency synthesizer as claimed in claim 15, wherein the adjust signal generator estimates that a phase difference between the feedback signal and the reference signal has achieved a total amount of delay, which is accumulated by how many delay units, according to the accumulation result, and generates the adjust signal according to the estimation result so as to select the output of a corresponding delay unit as the adjusted reference signal.

17. The frequency synthesizer as claimed in claim 15, wherein the adjust signal generator extracts a fractional part of the accumulation result, amplifies the fractional part of the accumulation result according to a ratio to obtain an amplified result, and the adjust signal generator further extracts an integer part of the amplified result to generate the adjust signal.

18. The frequency synthesizer as claimed in claim 17, wherein the phase adjustor selects the output of one of the delay units as the adjusted reference signal according to a value of the integer part.

19. The frequency synthesizer as claimed in claim 17, wherein the ratio relates to an amount of the delay units.

20. The frequency synthesizer as claimed in claim 17, wherein the ratio relates to the amount of delay of the delay units and an oscillation period of the VCO.
